(19) United States
(12) Patent Application Publication
(10) Pub. No.: US 2016/0112001 A1
(43) Pub. Date: Apr. 21, 2016

(54) SOLAR CELL ASSEMBLY COMPRISING SOLAR CELLS SHAPED AS A PORTION OF A CIRCLE

(71) Applicant: Emcore Solar Power, Inc., Albuquerque, NM (US)

(72) Inventors: Claiborne McPheeters, Albuquerque, NM (US); Daniel Derkacs, Albuquerque, NM (US)

(21) Appl. No.: 14/514,883

(22) Filed: Oct. 15, 2014

(51) Int. Cl. H01L 31/042; H01L 31/0687; H01L 27/146; H01L 31/0693

(52) U.S. Cl. CPC H02S 30/00; H01L 31/0693; H01L 31/0687; H01L 27/1469

(57) ABSTRACT

A solar cell assembly comprising a plurality of solar cells, each solar cell of the plurality of solar cells being shaped as a portion of a circle, the portion having at least one curved edge having a shape of the arc of the circumference of said circle and at least one straight edge, the portion having a surface area corresponding to not more than 50% of the surface area of the circle.

This makes it possible to make efficient use of the material of the wafer from which the solar cells are produced by reducing waste, while arrangement of the solar cells into rectangular unit cells enables construction of substantially rectangular solar cell arrays and assemblies that have their surface area covered substantially by solar cells with little area unoccupied by solar cells.

### REFERENCE TO RELATED APPLICATIONS

This application is related to co-pending U.S. patent application Ser. No. 14/498,071 filed Sep. 26, 2014.

### BACKGROUND OF THE DISCLOSURE

1. Field of the Disclosure

The disclosure relates to the field of photovoltaic power devices, and more particularly arrays of discrete solar cells.

2. Description of the Related Art

Photovoltaic devices, such as photovoltaic modules or CIC (Solar Cell+Interconnects+Coverglass) devices, comprise one or more individual solar cells arranged to produce electric power in response to irradiation by solar light. Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells due to the space that is left between adjacent solar cells due to their circular configuration (cf. U.S. Pat. Nos. 4,235,643 and 4,321,417).

However, solar cells are often produced from circular or substantially circular wafers. For example, solar cells for space applications are typically multi-junction solar cells grown on substantially circular wafers. These circular wafers are sometimes 100 mm or 150 mm diameter wafers. However, as explained above, for assembly into a solar array (henceforth, also referred to as a solar cell assembly), substantially circular solar cells, which can be produced from substantially circular wafers to minimize wasting wafer material and, therefore, minimize solar cell cost, are often not the best option, due to their low array fill factor, which increases the overall cost of the photovoltaic array or panel and implies an inefficient use of available space. Therefore the circular wafers are often divided into other form factors to make solar cells. The preferable form factor for a solar cell for space is a rectangle, such as a square, which allows for the area of a rectangular panel consisting of an array of solar cells to be filled 100% (henceforth, that situation is referred to as a “fill factor” of 100%), assuming that there is no space between the adjacent rectangular solar cells. However, when a single circular wafer is divided into a single rectangle, the wafer utilization is low. This results in waste. This is illustrated in FIG. 1, showing how conventionally, out of a circular solar cell wafer 100 a rectangular solar cell 1000 is obtained, leaving the rest of the wafer as waste 1001. This rectangular solar cell 1000 can then be placed side by side with other rectangular solar cells 1000 obtained from other wafers, thereby providing for efficient use of the surface on which the solar cells are placed (i.e., a high fill factor): a large W/m² ratio can be obtained, which depending on the substrate may also imply a high W/kg ratio, of great importance for space applications. That is, closely packed solar cells without any space between the adjacent solar cells is generally preferred, and especially for applications in which W/m² and/or W/kg are important aspects to consider. This includes space applications, such as solar power devices for satellites.

Space applications frequently use high efficiency solar cells, including multi junction solar cells and/or III/V compound semiconductor solar cells. High efficiency solar cell wafers are often costly to produce. Thus, the waste that has conventionally been accepted in the art as the price to pay for a high fill factor, that is, the waste that is the result of cutting the rectangular solar cell out of the substantially circular solar cell wafer, can imply a considerable cost.

Thus, the option of using substantially circular solar cells, corresponding to substantially circular solar cell wafers, to produce an array or assembly of solar cells, could in some cases become an interesting option. There is a trade-off between maximum use of the original wafer material and the fill factor. FIG. 2 shows how circular wafers can be packed according to a layout for maximum use of space, obtaining a fill factor in the order of 90%. This implies less wafer material is wasted than in the case of the option shown in FIG. 1, but also a less efficient use of the surface on which the solar cells are mounted, due to the lower fill factor. A further problem is that with this kind of layout, the pattern features a hexagonal unit cell 2000 (illustrated with broken lines in FIG. 2), which is non-optimal for producing a rectangular assembly of solar cells. The hexagonal unit cell is inconvenient for producing rectangular arrays of solar cells because the assembly of solar cells will not fit neatly to the edges or boundaries of a rectangular panel.

### SUMMARY OF THE DISCLOSURE

A first aspect of the disclosure relates to a solar cell assembly comprising a plurality of solar cells, each of said plurality of solar cells being shaped as a portion, such as a sector or segment, of a substantially circular wafer, said portion having at least one curved edge having substantially the shape of an arc of the circumference of the circle and at least one straight edge, and having a surface area corresponding to not more than 50% of the surface area of the circle, that is, the total surface area, of the circle. That is, each of said plurality of solar cells has a shape corresponding to the one that is obtained by cutting a substantially circular wafer into at least two pieces, such as according to a sector or segment of the circle defined by the circumference of the substantially circular solar cell wafer.

It has been found that by dividing a substantially circular wafer into segments or, maybe preferably, sectors, solar cells are obtained that can be packed with a high fill factor while, at the same time, producing a rectangular unit cell, which is preferred in the case of the production of substantially rectangular solar cell assemblies. For example, a square unit cell can be appropriate, allowing the unit cells to be rotated, for example, at the edges of the panel, simplifying interconnection. By using such an approach, wafer waste is minimized. Thus, by the division of the substantially circular wafer into portions such as segments or sectors, wafer utilization is maximized and at the same time a high fill factor is obtained in combination with a rectangular unit cell for the solar cell assembly. Thus, the disclosure provides for a flexible system that can often be advantageous to reach a good balance between the cost of the solar cell on the one hand and efficiency in terms of W/m² or W/kg of the solar cell assembly on the other hand. The disclosure may be especially useful and advantageous in the context of solar cells where the cost of the solar cell wafer is high, including many high efficiency solar cells, multi junction solar cells and III/V compound semiconductor solar cells. It provides for relatively low wafer waste, while at the same time providing for a relatively high fill factor, which can also be important, for example, when the total space allowed for a solar panel, such as on a satellite or rooftop, limits the maximum power that can be provided by the solar panel. The disclosure makes it possible to make use also of the material adjacent to the circumference of the circular wafer, without renouncing excessively on the fill factor and without renouncing on a rectangular unit cell. It has been found that it is possible to achieve >90% panel fill factor and to simultaneously achieve >90% wafer utilization, providing for a combined wafer and space utilization efficiency of >81%, if the mathematical product of the two aspects (panel fill factor and wafer utilization) is taken as a basis for calculating efficiency. Of course, in practice, it may be more important to enhance one of the two aspects than the other one, depending on issues such as the cost of wafer material and cost or availability of space.

In some embodiments of the disclosure, one portion of the solar cell corresponding to what was originally the circumference of the wafer may be modified to a flat portion or a ‘v’-shaped notch, for example. This is especially the case when the solar cells are obtained from a substantially circular wafer having a flat portion or a ‘v’ notch in correspondence with its circumference. This is often the case. When “circular wafers” or ‘circles’ are referred to herein, it is understood that in practice such shapes may be fully circular, but that the principles disclosed apply equally to substantially circular shapes or wafers, as are often used in practice.

In some embodiments of the disclosure, the solar cell assembly is made up entirely of this kind of solar cell; in other embodiments of the disclosure, the solar cell assembly includes also other kinds of solar cells, for example, completely circular solar cells and/or rectangular solar cells. However, for simplicity in terms of layout, assembly and interconnection, it is often preferred to use solar cells all having the same shape and/or size.

In some embodiments of the disclosure, the curved edge of said plurality of solar cells has a length corresponding to at least 45 degrees, preferably at least 60 degrees, more preferably at least 90 degrees, of the circumference of the circle, and/or a size of at least 10%, preferably at least 25%, of the area of the circle. The use of relatively large solar cells can be useful to reduce the amount of work related to assembly and interconnections.

In some embodiments of the disclosure, said plurality of solar cells are substantially shaped as sectors of said circle. This option is often preferred, as it has been found practical to implement: it allows for full use of substantially all of the material of the substantially circular wafer and for the production of substantially identical solar cells which can then be assembled to form the array using the repetition of a simple basic pattern, without any need to accommodate a large number of differently shaped solar cells. The term “substantially” is used to encompass minor variants, such as the cases wherein there is one or more additional flat portions corresponding to the above-mentioned flat portion of the circumference present in many substantially circular wafers used for the production of solar cells.

In some embodiments of the disclosure, said plurality of solar cells comprises a plurality of solar cells substantially shaped as quadrants, that is, as quarters of a substantially circular wafer, with two straight edges at substantially 90 degrees to each other. A circular wafer can be split into four quadrants without substantial waste of material, and the use of quadrants has been found to be beneficial as the quadrants can be fitted into rectangular unit cells with a high fill factor, in the order of 90% or greater than 90%. Of course, a circular wafer can be split into smaller sectors which can, for example, be interconnected to form a quadrant, but this may at least sometimes be inefficient as interconnection implies additional costs. Thus, in many embodiments of the disclosure, it can be preferred to use only quadrants, or at least a substantial number and/or proportion of quadrants.

In some embodiments of the disclosure, said plurality of solar cells comprises a plurality of solar cells substantially shaped as semicircles. Semicircles may be less attractive than quadrants in what concerns flexibility and/or fill factor, but can nevertheless be used in embodiments of the disclosure.

In some embodiments of the disclosure, said plurality of solar cells comprises both solar cells shaped as quadrants and solar cells shaped as semicircles. For example, in some embodiments of the disclosure, a semicircle and two quadrants can be combined into a unit cell, one example of which is illustrated in FIG. 5. The use of one semicircle instead of two quadrants can serve to limit the number of interconnections.

In some embodiments of the disclosure, a plurality of the solar cells are arranged so that a straight edge of one solar cell is placed against the straight edge of another one of the solar cells. For example, the straight edges can be placed against each other where some unit cells meet.

In some embodiments of the disclosure, the solar cells are arranged in a pattern formed by an array of rectangular unit cells, each unit cell encompassing an identical or substantially identical arrangement of at least two solar cells. This can be an advantage over the use of tightly packed solar cells having a circular shape, that is, shaped as substantially full circles. If one or more substantially fully circular solar cells are efficiently fitted into the area of a rectangle, the rectangle being a unit cell useful for building a rectangular array of unit cells, that is, with rows and columns of aligned unit cells, the fill factor will be relatively low (i.e., in the order of 60%), which is a disadvantage. If, on the other hand, the circular unit cells are placed as close together as possible, the unit cell will be hexagonal, as explained in relation to FIG. 2, which is a disadvantage for fitting neatly into a rectangular or substantially rectangular solar cell assembly comprising an array of unit cells. Contrarily, with the present disclosure, it is possible to obtain rectangular unit cells with a rather high fill factor, such as greater than 90%, which fit neatly into a rectangular or substantially rectangular solar cell assembly comprising an array of unit cells.

In some embodiments of the disclosure, each unit cell encompasses at least two solar cells arranged so that the curved edge of each one of said solar cells is placed against the curved edge of another one of said solar cells. This provides for a high fill factor of the unit cell and, accordingly, of a rectangular or substantially rectangular solar cell assembly made up of a row or array of unit cells, such as an array comprising rows and columns of unit cells.

In some embodiments of the invention, each unit cell encompasses at least two solar cells arranged so that a flat portion at a curved edge of one solar cell is placed against a flat portion at a curved edge of another one of said solar cells. These flat portions can in some embodiments of the invention originate from original flat portions of the wafer, or they can have been added by cropping the solar cells at their curved edges.

In some embodiments of the disclosure, the solar cells have been obtained by dividing a substantially circular wafer into a plurality of substantially identical portions, such as into substantially identical sectors. Thus, full advantage is taken of the material of the wafer, thereby minimizing the cost per area of solar cell. The use of identical portions can simplify the assembly. Preferably, at least the size of the portions is substantially the same, as this provides for substantially identical production of electrical current, which simplifies the interconnection of solar cells.

Another aspect of the disclosure relates to a method of producing solar cells for a solar cell assembly, comprising the step of dividing at least one substantially circular solar cell wafer into a plurality of portions, each portion being a solar cell, at least some of said portions having at least one substantially straight edge and one substantially curved edge corresponding to an arc of the circumference of the solar cell wafer. In some embodiments of the disclosure, said portions are sectors of the circular solar cell wafer, for example quadrants or semicircles, as explained above.

A further aspect of the disclosure relates to a method of producing a solar cell assembly, comprising the steps of providing a plurality of solar cells with the method described above, and assembling the solar cells to provide a substantially rectangular solar cell assembly.

In some embodiments of the disclosure, the method comprises the step of arranging the solar cells according to a pattern of identical rectangular unit cells arranged in an array forming the substantially rectangular solar cell assembly, each unit cell including an identical arrangement of at least two solar cells. In some embodiments of the disclosure, the solar cells are substantially identical. The use of substantially identical solar cells, or at least of solar cells having substantially the same effective surface area, often simplifies the interconnection of solar cells, as there is less need to take differences in electrical current production into account.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1 schematically illustrates a prior art arrangement for producing a closely packed solar cell array out of square solar cells obtained from a circular solar cell wafer.

FIG. 2 schematically illustrates how circular solar cells packed to obtain a maximum fill factor imply a hexagonal unit cell for the arrangement of solar cells in an array of solar cells, or a solar cell assembly.

FIG. 3 schematically illustrates how a solar cell assembly can be produced of solar cells consisting of quadrants cut from a circular wafer, in accordance with an embodiment of the disclosure.

FIG. 4 schematically illustrates the unit cell in the embodiment of FIG. 3.

FIG. 5 schematically illustrates a unit cell in an alternative embodiment of the disclosure, based on the use of both quadrants semicircular solar cells.

FIG. 6 schematically illustrates a unit cell based on four quadrants cut from a circular wafer having two flat portions at the circumference.

FIG. 7 schematically illustrates how a square solar cell with cropped corners can be obtained from a circular wafer and fitted into a square unit cell.

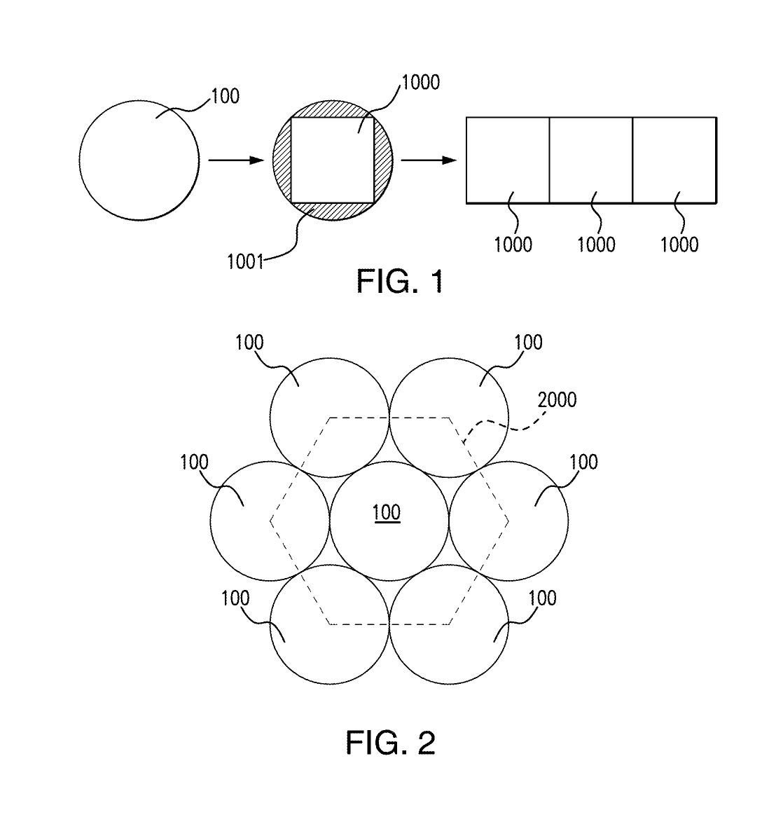

### DETAILED DESCRIPTION

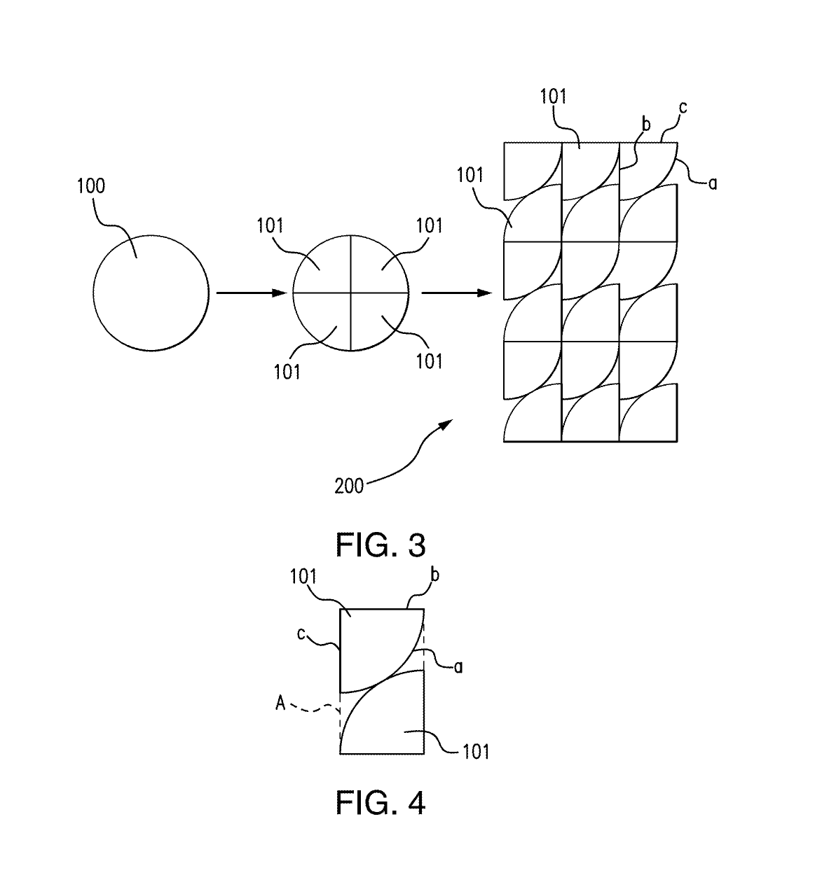

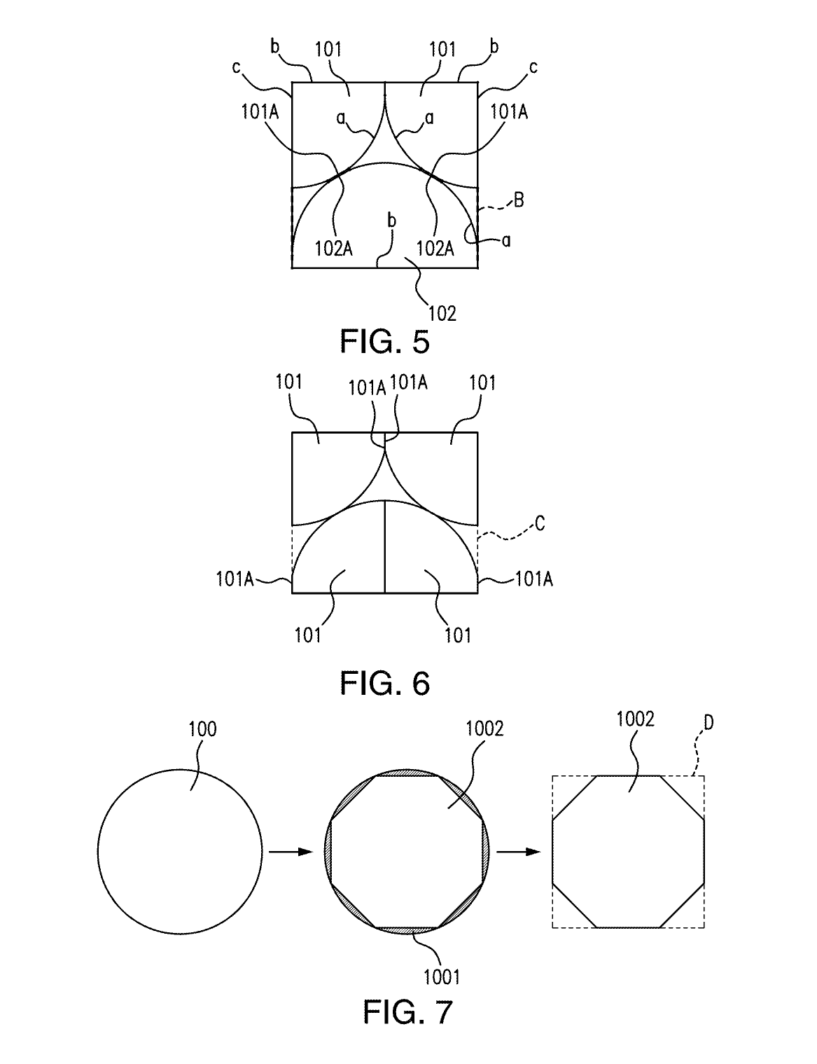

FIG. 3 schematically illustrates how, in accordance with an embodiment of the disclosure, a substantially circular solar cell wafer 100 is divided into four sectors (in the figure, the sectors are quadrants), thus producing four solar cells 101 each having a curved edge a, corresponding to the arc portion of the circumference of the circular wafer 100, and two substantially straight edges b and c extending at a right angle (90 degrees). These solar cells can be packed to form a solar cell assembly 200 as illustrated in FIG. 3, that is, in accordance with a pattern formed by an array of equal rectangles or “unit cells” A (as shown in FIG. 4), these rectangles being arranged adjacent to each other forming an array. Each rectangle encompasses two solar cells 101, fitting efficiently into the area of the rectangle or unit cell A as shown in FIG. 4. These unit cells can fill a rectangular panel or surface with a fill factor of 100%. For example, the solar cell assembly 200 of FIG. 3 comprises an array of 3×3 unit cells of the type shown in FIG. 4. Thus, the fill factor of the solar cells on the panel, that is, the fill factor of the solar cells 101 in the entire solar cell array 200, will be the same as the fill factor of the solar cells 101 in the unit cell A. It has been found that the use of solar cells shaped substantially as quadrants of a circle can at least sometimes be an appropriate solution, taking into account how the quadrants can fit into a rectangular unit cell with a fill factor of about 90% or greater, that is, with a rather high fill factor, cf. FIG. 4. FIG. 5 shows the unit cell B in accordance with an alternative embodiment in which one or more substantially circular wafers have been divided into quadrants and/or halves in order to make three solar cells, one cell corresponding to a semicircle with one curved edge a and one straight edge b, and the other two cells corresponding to quadrants, each with one curved edge a and two straight edges b and c. The use of quadrants only may be beneficial for enhancing the fill factor of the unit cell, but combining semicircular cells and quadrants can be useful to limit the number of interconnections while obtaining a still high fill factor of about 90% or greater. FIG. 5 also shows how in the illustrated embodiment of the invention, in order to additionally improve the fill factor, the solar cells have been provided with straight portions 101A and 102A at their curved edges. These straight portions can correspond to flat portions of the original wafer, or be added by cropping the solar cells to improve the fill factor. In other embodiments of the invention, no such straight portions are present at the curved edges, or only some of the solar cells feature such straight portions at their curved edges.

FIG. 6 shows an arrangement in which the substantially circular wafers out of which the solar cells 101 have been obtained had so-called flats. Semiconductor wafers are often supplied with a portion of the circumference removed; this part is sometimes referred to as the “bottom flat”. During processing, one or more corresponding portions can be removed from part of the circumference, so that there are two or more flat portions. FIG. 6 illustrates how four quadrants obtained from one or more of this kind of wafer can be arranged in correspondence with a rectangular, and in some cases square, unit cell C. The flat portion 101A of each quadrant, that is, the portion corresponding to the flat part of the circumference of the wafer prior to dividing it into multiple solar cells, is placed against the boundaries of the unit cell C or against the flat portion 101A of an adjacent solar cell. This provides for a high fill factor, such as 90% or greater.

FIG. 7 schematically illustrates how a square solar cell with cropped corners 1002 can be produced from a circular wafer 100. FIG. 7 shows how the solar cell 1002 fits into a square unit cell D. As discussed, square unit cells are useful for building assemblies because they can be rotated, simplifying assembly, without disrupting the array pattern. FIG. 7 illustrates how a square unit cell is derived from a square solar cell with truncated corners, which compromises wafer utilization for a square unit cell. Such a compromise is not preferred, because it sacrifices wafer utilization due to the waste 1001 of wafer material, and therefore increases solar cell cost, while achieving a moderate fill factor in the order of 80%. In contrast, the new method described in this disclosure enables >90% wafer utilization and >90% fill factor and, in some embodiments, produces square unit cells, which may be favorable to non-equilateral rectangles. The method described here is therefore preferred, for example, to the one illustrated in FIG. 7, and to other methods of producing rectangular or square unit cells at the expense of wafer utilization or fill factor

In this text, the term “comprises” and its derivations (such as “comprising”, etc.) should not be understood in an excluding sense, that is, these terms should not be interpreted as excluding the possibility that what is described and defined may include further elements, steps, etc.

The disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A solar cell assembly comprising a plurality of solar cells, each solar cell of the plurality of solar cells substantially being shaped as a sector of a circle, the portion having at least one curved edge having a shape of an arc of a circumference of said circle and at least one straight edge, the portion having a surface area corresponding to not more than 50% of a surface area of said circle,
wherein the solar cells are arranged in a pattern formed by an array of rectangular unit cells, each unit cell encompassing a substantially identical arrangement of at least two solar cells, and
wherein each unit cell encompasses at least two solar cells arranged so that the curved edge of each one of said solar cells is placed against the curved edge of another one of said solar cells.

2. The solar cell assembly of claim 1, wherein the curved edge of the plurality of solar cells has a length corresponding to at least 45 degrees of the circumference of the circle.

3. (canceled)

4. The solar cell assembly of claim 1, wherein the plurality of solar cells comprises a plurality of solar cells substantially shaped as quadrants of circles.

5. The solar cell assembly of claim 1, wherein the plurality of solar cells comprises a plurality of solar cells shaped as semicircles.

6. The solar cell assembly of claim 1, wherein the plurality of solar cells comprises a plurality of solar cells shaped as semicircles and quadrants of circles.

7. The solar cell assembly of claim 1, wherein a plurality of the solar cells are arranged so that a straight edge of one solar cell is placed against the straight edge of another one of the solar cells.

8-9. (canceled)

10. The solar cell assembly of claim 1, wherein each unit cell encompasses at least two solar cells arranged so that a flat portion at a curved edge of one solar cell is placed against a flat portion at a curved edge of another one of said solar cells.

11. The solar cell assembly of claim 1, wherein the solar cells have been obtained by dividing one or more substantially circular wafers into a plurality of substantially identical sectors.

12. A method of producing a solar cell assembly comprising:
dividing at least one substantially circular solar cell wafer into a plurality of portions, each portion being a solar cell, at least some of the portions having at least one substantially straight edge and one substantially curved edge corresponding to an arc of the circumference of the solar cell wafer, wherein said portions are sectors of the circular solar cell wafer;
arranging and assembling the solar cells according to a pattern of identical rectangular unit cells arranged in an array forming a substantially rectangular solar cell assembly, each unit cell including an identical arrangement of at least two solar cells,
wherein each unit cell encompasses at least two solar cells arranged so that the curved edge of each one of said solar cells is placed against the curved edge of another one of said solar cells.

13. (canceled)

14. The method of claim 12, wherein said sectors are quadrants of circles or are semicircles or both.

15-16. (canceled)

17. The method of claim 12, wherein the solar cells are substantially identical.

18. The solar cell assembly of claim 1, wherein the curved edge of the plurality of solar cells has a length corresponding to at least 90 degrees.

19. The solar cell assembly of claim 1, wherein the curved edge of the plurality of solar cells has a length corresponding to 180 degrees.

20. The solar cell assembly of claim 1, wherein the sector of the circle is not a semicircle.

21. The method of claim 12, wherein the sector of the circle is not a semicircle.
